(19) United States
(12) Patent Application Publication
(10) Pub. No.: US 2023/0315944 A1
(43) Pub. Date: Oct. 5, 2023

(54) METHOD FOR CLASSIFYING MOVEMENTS

(71) Applicant: Robert Bosch GmbH, Stuttgart (DE)

(72) Inventor: Thomas Nilsson, Malmö (SE)

(21) Appl. No.: 18/169,314

(22) Filed: Feb. 15, 2023

(30) Foreign Application Priority Data
Mar. 31, 2022 (DE) 10 2022 203 199.7

(51) Int. Cl. G06F 30/20

(52) U.S. Cl. CPC G06F 30/20

(57) ABSTRACT

A method for classifying movements. In the method, sensor data are first received. A characteristic measured variable is then ascertained from the received sensor data, and a movement sequence is classified based on the characteristic measured variable. The sensor data are input into a mathematical model, which includes coefficient(s) and is dependent on the characteristic measured variable. The mathematical model is selected based on the movement sequence. An equation of state of a sensor data value is determined, the equation of state including the coefficient(s). The sensor data value maps a curve of the characteristic measured variable. The coefficient(s) are adjusted based on the sensor data, the coefficient being kept within a predetermined range during the adjustment. The mathematical model is adjusted on the basis of the adjusted coefficient. An item of information is output, the type of the classified movement being part of the information.

### CROSS REFERENCE

The present application claims the benefit under 35 U.S.C. § 119 of German Patent Application No. DE 10 2022 203 199.7 filed on Mar. 31, 2022, which is expressly incorporated herein by reference in its entirety.

### FIELD

The present invention relates to a method for classifying movements, to an arithmetic logic unit configured to carry out the method, and to a sensor system.

### BACKGROUND INFORMATION

Movement sensors that can be used to classify a movement are available in the related art. Sensors of this kind can, for example, be used in fitness and/or sports and worn on a human body. If certain fitness or sports exercises are then performed, the sensors can recognize and classify the type of the movement and optionally recognize and output a number of repetitions of the movement. U.S. Pat. No. 10,540,597 B1 describes a system of this kind in which data from a gyroscope and an accelerometer are evaluated using Kalman filters, the type of the movement is classified, and then a number of repetitions is output. A method for classifying movements in which, in particular, a frequency of a repeated movement is evaluated is used for this purpose. In this case, Kalman filters can be used in particular to correct information ascertained from the sensor data in order to enhance the measurement accuracy and the probability that a classification is correct. In particular, in Kalman filters a phase of a mathematical model is changed while the sensor data are processed in the mathematical model.

### SUMMARY

An object of the present invention is to provide an improved method for classifying movements, an arithmetic logic unit for carrying out the method, and an improved sensor system.

These objects may be achieved by the features of the present invention. Advantageous developments and example embodiments of the present invention are disclosed herein.

According to an example embodiment of the present invention, in a method for classifying movements, sensor data are first received. In this case, the sensor data may be output by a sensor directly via electrical lines, wires, cables, or the like, or via a wireless link. In both cases, the sensor data can be made available via a signal input of an arithmetic logic unit. The sensor may in particular already comprise an A/D converter for converting a physical measured value into a digital signal. In particular, the sensor may be an accelerometer and/or a gyroscope and/or a pressure sensor and/or a magnetic-field sensor, but it is not limited to these examples. A characteristic measured variable is then ascertained from the received sensor data, and a movement sequence is classified on the basis of the characteristic measured variable. In the process, the characteristic measured variable may, for example, include a movement frequency and the movement may be classified on the basis of the movement frequency. In particular, different fitness or sports exercises may have different movement frequencies, so conclusions on which fitness or sports exercise is being performed can be drawn on the basis of the movement frequency. Other repetitive movement sequences besides fitness or sports exercises can also be recognized.

Next, the sensor data are input into a mathematical model, wherein the mathematical model includes at least one coefficient and is dependent on the characteristic measured variable. The mathematical model is selected on the basis of the movement sequence. In particular, the mathematical model can thus be selected in accordance with the recognized or classified movement sequence. Then, an equation of state of a sensor data value is determined, wherein the equation of state includes the at least one coefficient. In the process, the sensor data value maps a curve of the characteristic measured variable. Next, the at least one coefficient is adjusted on the basis of the sensor data, wherein the coefficient is additionally kept within a predetermined range during the adjustment. Additionally, the mathematical model is adjusted on the basis of the adjusted coefficient. Additionally, an item of information is output, for example via a signal output, wherein the type of the classified movement is part of the information.

In the method described in the related art, the coefficients are fixed and are not changed. Only a phase is changed in order to ascertain the equations of state and the mathematical model. Using the method according to the present invention, different executions of the fitness or sports exercise can be mapped more accurately, for example on the basis of different physical abilities or if the person is tiring, thereby achieving greater accuracy when classifying the movement. By way of the predetermined range in which the changed coefficients are kept, classification errors, i.e., supposedly recognizing an incorrect movement, that is to say, a movement that is not performed, can be reduced. Additionally, person-specific differences in the execution of fitness or sports exercises can thus be taken into account, and in particular a sensor system can be adjusted to a user. By way of example, a particular user may execute a fitness or sports exercise differently from other users. The conventional methods from the related art cannot take these differences into account as the mathematical model is fixed.

In one specific example embodiment of the present invention, the sensor data are predicted using the adjusted mathematical model. This allows data to be acquired more accurately, thus allowing the movement to be classified more accurately too.

In one specific example embodiment of the present invention, the predetermined range is selected on the basis of the classified movement sequence. Therefore, classification errors in particular can be reduced further.

In one specific example embodiment of the present invention, reading the sensor data into the mathematical model, determining the equation of state of the sensor data value, adjusting the at least one coefficient, and adjusting the mathematical model are each carried out multiple times. As a result, even relatively long sequences of sensor data can be used, and the accuracy of the classification can additionally be increased further. Additionally, the sensor data can optionally be predicted multiple times.

In one specific embodiment of the present invention, the information additionally includes a measured variable that is characteristic of the movement sequence. By way of example, this may be a movement frequency or a number of repetitions of a fitness or sports exercise. As a result, for example, the movement frequency and number of repetitions of a fitness or sports exercise can also be output.

In one specific embodiment of the present invention, the mathematical model includes a Kalman filter, an expanded Kalman filter, or an unscented Kalman filter. These filters have proven suitable for the method and allow movements to be classified. In these embodiments in particular, improved accuracy can be achieved by the additional sensor data prediction and by the method steps being run through multiple times.

In one specific embodiment of the present invention, the equation of state of the sensor data value includes a Fourier series. The characteristic measured variable includes a frequency of a movement. In this case, there are at least two coefficients, which are Fourier coefficients of the Fourier series. More than two Fourier coefficients may also be provided. The predetermined range is determined on the basis of the Fourier coefficient(s) of the Fourier series. This allows for a simple mathematical transposition of the predetermined range. In the process, the Fourier coefficients can be adjusted such that the predetermined ranges for different movements do not overlap, meaning that the coefficients are each adjusted within a recognized movement.

In one specific embodiment of the present invention, an excursion and a phase are determined using the Fourier coefficients. When adjusting the Fourier coefficients, a maximum adjustment amount is used. The maximum adjustment amount is selected such that, in the event that the predetermined range is departed from, the excursion is scaled such that the excursion is within the predetermined range, and, in the event that the predetermined range is departed from due to the phase once the excursion has been scaled, the phase is changed such that the predetermined range is adhered to.

In one specific embodiment of the present invention, the information corrected on the basis of the mathematical model and ascertained from the sensor data is also used for classifying the movement. This can further improve the classification.

In one specific embodiment of the present invention, the adjusted coefficient and the adjusted model are stored in a memory. By way of example, this allows a user to repeat a fitness or sports exercise and makes it possible, when the fitness or sports exercise is being repeated, to consult a mathematical model that has already been adjusted to the movement sequence of the user.

In one specific embodiment of the present invention, at least one further coefficient is added to the mathematical model when it is established that the sensor data are then a better fit for the mathematical model. This can entail, for example, changing the number of Fourier coefficients. By way of example, this can be configured as reinforcement learning.

The present invention further relates to an arithmetic logic unit comprising a signal input, a processor, and a signal output. The processor comprises a program that causes the arithmetic logic unit to receive sensor data via the signal input, and then to carry out the method according to the present invention and output the information via the signal output. In this case, the processor can include the program in the form of an accordingly equipped piece of hardware, for example a chip adjusted to the program sequence, or the program can be processed in the processor in the form of software.

The arithmetic logic unit may have a memory, wherein the processor comprises a program that causes the arithmetic logic unit to store the adjusted coefficient and the adjusted model in the memory.

The present invention further relates to a sensor system that comprises a sensor for determining sensor data and an arithmetic logic unit according to the present invention. The sensor is connected to the signal input. Sensor data ascertained using the sensor can be communicated to the signal input.

Exemplary embodiments of the present invention are explained on the basis of the figures.

### BRIEF DESCRIPTION OF THE DRAWINGS

FIG. 1 is a flow diagram of a method according to an example embodiment of the present invention.

FIG. 2 shows an arithmetic logic unit and a sensor system, according to an example embodiment of the present invention.

FIG. 3 shows a person executing a fitness exercise.

FIG. 4 shows an adjustment of coefficients in a first predetermined range, according to an example embodiment of the present invention.

FIG. 5 shows an adjustment of coefficients in a second predetermined range, according to an example embodiment of the present invention.

FIG. 6 shows an adjustment of coefficients in a third predetermined range, according to an example embodiment of the present invention.

FIG. 7 shows a curve of an activity rate for activating and deactivating an adjustment, according to an example embodiment of the present invention.

### DETAILED DESCRIPTION OF EXAMPLE EMBODIMENTS

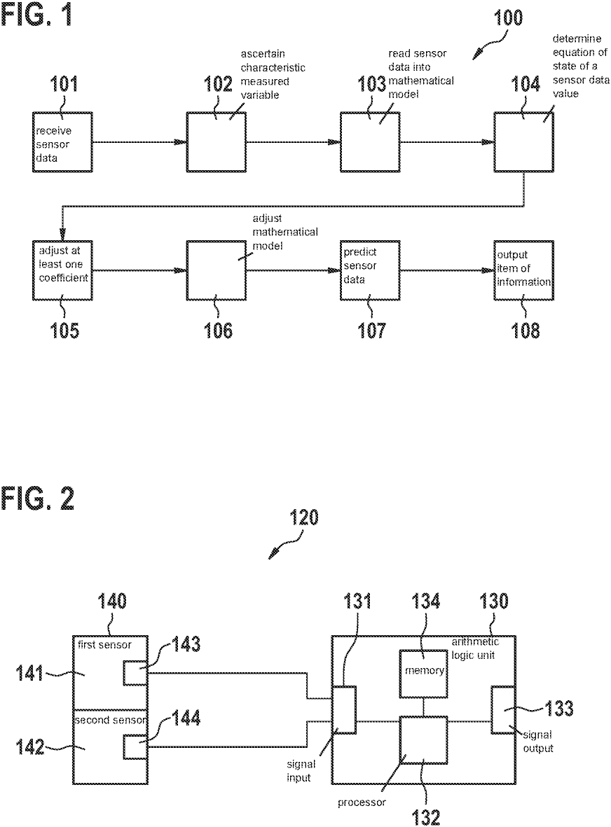

FIG. 1 is a flow diagram 100 of a method for classifying movements. In a first method step 101, sensor data are received. In a second method step 102, a characteristic measured variable is ascertained from the received sensor data, and a movement sequence is classified on the basis of the characteristic measured variable. In the process, the characteristic measured variable may, for example, include a movement frequency and the movement may be classified on the basis of the movement frequency. In particular, different fitness or sports exercises may have different movement frequencies, so conclusions on which fitness or sports exercise is being performed can be drawn on the basis of the movement frequency. In a third method step 103, the sensor data are read into a mathematical model, wherein the mathematical model includes at least one coefficient and is dependent on the characteristic measured variable. The mathematical model is selected on the basis of the movement sequence. In particular, the mathematical model can thus be selected in accordance with the recognized or classified movement sequence. In a fourth method step 104, an equation of state of a sensor data value is determined, wherein the equation of state includes the at least one coefficient. In the process, the sensor data value maps a curve of the characteristic measured variable. In a fifth method step 105, the at least one coefficient is adjusted on the basis of the sensor data, wherein the coefficient is additionally kept within a predetermined range during the adjustment. In a sixth method step 106, the mathematical model is adjusted on the basis of the adjusted coefficient. In an optional seventh method step 107, the sensor data are then predicted using the adjusted mathematical model. The seventh method step 107 is not entirely necessary. In an eighth method step 108, an item of information is output, for example via a signal output, wherein the type of the classified movement is part of the information.

Reading the sensor data into the mathematical model, determining the equation of state of the sensor data value, adjusting the at least one coefficient, adjusting the mathematical model, and, where applicable, predicting the sensor data, i.e., the third method step 103, the fourth method step 104, the fifth method step 105, the sixth method step 106, and, where applicable, the seventh method step 107, can each be carried out multiple times. As a result, even relatively long sequences of sensor data can be used, and the accuracy of the classification can additionally be increased further.

In one exemplary embodiment, the information additionally includes a measured variable that is characteristic of the movement sequence. By way of example, this may be a movement frequency or a number of repetitions of a fitness or sports exercise. As a result, for example, the movement frequency and number of repetitions of a fitness or sports exercise can also be output in the eighth method step 108.

In one exemplary embodiment, the mathematical model includes a Kalman filter, an expanded Kalman filter, or an unscented Kalman filter. These filters have proven suitable for the method and allow movements to be classified.

FIG. 2 shows a sensor system 120 that comprises a sensor 140 for determining sensor data and an arithmetic logic unit 130. The arithmetic logic unit 130 has a signal input 131, a processor 132, and a signal output 133. The processor 132 comprises a program that causes the arithmetic logic unit 130 to receive sensor data via the signal input 131, and then to carry out the method according to the present invention as explained in conjunction with FIG. 1 and output the information via the signal output 133. In this case, the processor 132 can include the program in the form of an accordingly equipped piece of hardware, for example a chip adjusted to the program sequence, or the program can be processed in the processor 132 in the form of software.

FIG. 2 shows that the arithmetic logic unit 130 optionally has a memory 134, wherein the processor 132 comprises a program that causes the arithmetic logic unit 130 to store the adjusted coefficient and the adjusted model in the memory 134. In the flow diagram 100 in FIG. 1, this can be carried out as an additional method step after the sixth method step 106. If the adjusted coefficient and the adjusted model are stored in the memory 134, this allows a user, for example, to repeat a fitness or sports exercise and makes it possible, when the fitness or sports exercise is being repeated, to consult a mathematical model that has already been adjusted to the movement sequence of the user.

In the embodiment in FIG. 2, the sensor 140 consists of a first sensor 141 and a second sensor 142. By way of example, the first second 141 may comprise a gyroscope whereas the second sensor 142 comprises an accelerometer. However, a different number of sensors 141, 142, or different types of sensors, can also be provided. The first sensor 141 is connected to the signal input 131 of the arithmetic logic unit 130 via a first sensor output 143. The second sensor 142 is connected to the signal input 131 of the arithmetic logic unit 130 via a second sensor output 144. Sensor data ascertained using the sensor 140 can thus be communicated to the signal input 131. In this case, as shown in FIG. 2, the sensor data may be output by the sensor 140 directly via electrical lines, wires, cables, or the like. Alternatively, they can be output via a wireless link. The sensor 140 may in particular already comprise an A/D converter for converting a physical measured value into a digital signal.

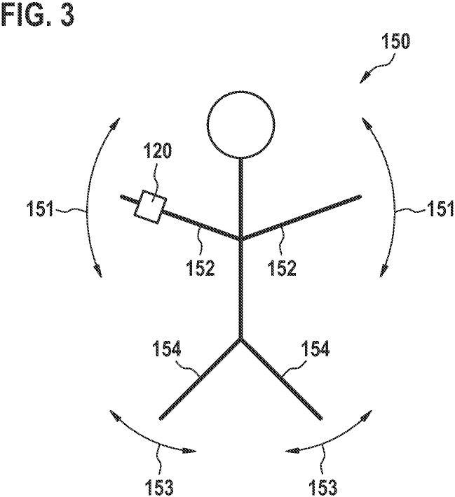

FIG. 3 shows a person 150 executing a fitness or sports exercise. A first movement 151 of the arms 152 and a second movement 153 of the legs 154 are being performed in this case. To ascertain and classify the fitness or sports exercise, the person 150 is wearing a sensor system 120 on their arm 152; said sensor system can have a construction similar to that in FIG. 2. In this case, the movements of the arm 152 can be recognized using the sensor system 120 and associated with the sports and fitness exercise (an exercise referred to as a jumping jack in the example in FIG. 3).

In one of the embodiments explained in conjunction with FIGS. 1 to 3, the equation of state of the sensor data value includes a Fourier series. The characteristic measured variable includes a frequency of a movement. The at least one coefficient is a Fourier coefficient of the Fourier series, although a plurality of Fourier coefficients can also be provided. The predetermined range is determined on the basis of the Fourier coefficient(s) of the Fourier series. This allows for a simple mathematical transposition of the predetermined range. In the process, the Fourier coefficients can be adjusted such that the predetermined ranges for different movements do not overlap, meaning that the coefficients are each adjusted within a recognized movement.

In particular, a parameterized equation of state for a dimension of the sensor 140 for a time range t can be described using the formula:

$${h}_{i} \left({θ}_{t}\right) = {c}_{0 , i} + {\sum }_{k = 1}^{N} {c}_{k , i} cos \left(k {θ}_{t}\right) + {s}_{k , i} sin \left(k {θ}_{t}\right)$$

where θₜθ_t corresponds to the phase over time t, and C_{0,i} corresponds to a signal offset. C_{k,i} and S_{k,i} are the Fourier coefficients, and k corresponds to the frequency component, where k=1 corresponds to the fundamental and k>1 corresponds to the harmonics. N is the number of possible vibrations (fundamentals and harmonics). The composition of this formula including the Fourier coefficients can correspond to the determination of an equation of state of a sensor data value of the fourth method step 104.

The classification and, where applicable, the determination of the measured variable that is characteristic of the movement sequence can be carried out by determining the phase θₜ as being between 1 and M for all sensor dimensions i by using an expanded Kalman filter, for example, by way of predetermined Fourier parameters: 0_t

$${r}_{i} = {\left\{{c}_{k , i} , {s}_{k , i}\right\}}_{k = 1}^{N}$$

This is known in principle from the related art.

When adjusting the at least one coefficient of the fifth method step 105, a quadratic error equation

$${f}_{i} \left({r}_{i}\right) = \frac{1}{L} {\sum }_{j = 1}^{L} {\left({h}_{i} \left({θ}_{j} , {r}_{i}\right) - {y}_{j}\right)}^{2}$$

can be determined. This can be done such that

$${f}_{i} \left({r}_{i}\right) , i = 1 , 2 , … , M$$

is minimized for each sensor dimension and the relationships

$${P}_{0 , i}^{m i n} \leq p \left({c}_{0 , i}\right) \leq {P}_{0 , i}^{m a x}$$

$${P}_{k , i}^{m i n} \leq p \left({c}_{k , i} , {s}_{k , i}\right) \leq {P}_{k , i}^{m a x} , k = 1 , 2 , … , N$$

$$- {\text{Θ}}_{k , i}^{m a x} \leq a \left({c}_{i k , i} , {s}_{k , i}\right) \leq {\text{Θ}}_{k , i}^{m a x} , k = 1 , 2 , … , N$$

are adhered to. In this case, p denotes an excursion, which can be calculated using

$$p \left({c}_{k , i} , {s}_{k , i}\right) = \sqrt{{c}_{k , i} {}^{2} + {s}_{k , i} {}^{2}}$$

and a corresponds to the angle predetermined by C_{k,i} and S_{k,i}. In this case, the aim is not an exact solution to the problem but rather an approximation that is accurate enough. The boundary conditions of the excursion and direction are provided firstly to avoid the fitness and sports exercise being associated with the wrong exercises and secondly also to prevent large deviations from the intended parameters for the exercise.

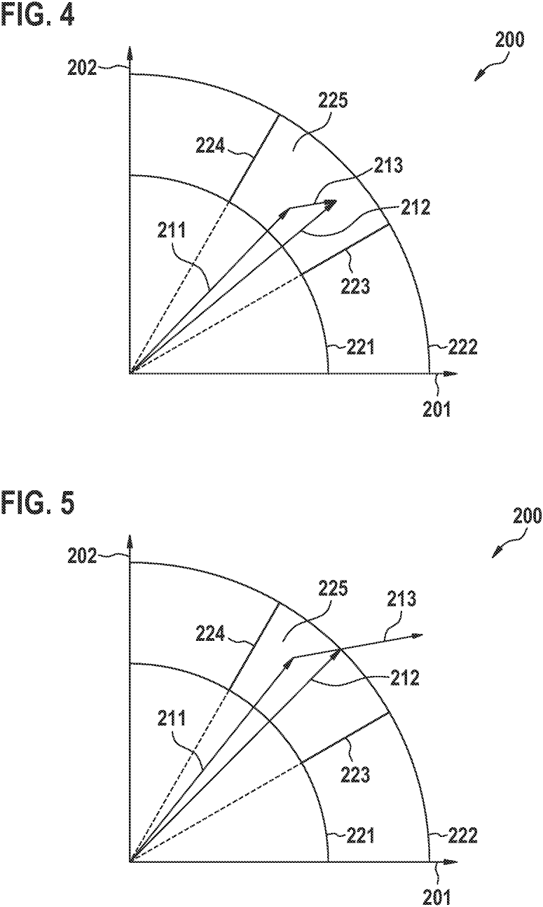

FIG. 4 is a diagram 200 of an adjustment of this kind, in which the Fourier coefficient C_{k,i} is plotted on an x axis 201 and the Fourier coefficient S_{k,i} is plotted on a y axis 202. A first measurement signal 211 during a first pass is defined by the plotted Fourier coefficients. In this case, the first measurement signal 211 is greater than a minimum excursion 221 and less than a maximum excursion 222, the minimum excursion 221 and the maximum excursion 222 being indicated by way of quadrants in the diagram 200. The direction of the first measurement signal 211 is such that it is above a minimum angle 223 and below a maximum angle 224. The first measurement signal 211 is thus within a predetermined range 225 defined by the minimum excursion 221, the maximum excursion 222, the minimum angle 223, and the maximum angle 224. A second measurement signal 212 during a second pass is likewise defined by the plotted Fourier coefficients. A change 213 depicts a transition from the first measurement signal 211 to the second measurement signal 212. Since the second measurement signal 212 is also within the predetermined range 225, no adjustments need to be made. Deviations in the execution of the fitness or sports exercise can be depicted by way of the change 213, the predetermined range 225 making it possible firstly to avoid the fitness and sports exercise being associated with the wrong exercises and secondly also to prevent large deviations from the intended parameters for the exercise.

To be able to adjust the Fourier coefficients, it may be provided to consider one small step in each case toward gradients of the equation of state. This can be described by way of the formulas:

$$\frac{\partial {f}_{i}}{\partial {c}_{k , i}} = \left\{\begin{matrix}\left({h}_{i} \left({θ}_{j}\right) - {y}_{j}\right) , k = 0 \\ 2 cos \left(k {θ}_{j}\right) \left({h}_{i} \left({θ}_{j}\right) - {y}_{j}\right) , k = 1 , 2 , 3 , … , N\end{matrix}\right\}$$

$$\frac{\partial {f}_{i}}{\partial {s}_{k , i}} = 2 sin \left(k {θ}_{j}\right) \left({h}_{i} \left({θ}_{j}\right) - {y}_{j}\right) , k = 1 , 2 , 3 , … , N$$

At a time j, the Fourier coefficients can be adjusted in the fifth method step 105 using the formulas:

$${k , i}_{} = {c}_{k , i}^{j} + γ \left(\frac{\partial {f}_{i}}{\partial {c}_{k , i}^{j}}\right) , k = 0 , 1 , 2 , … , N$$

$${k , i}_{} = {s}_{k , i}^{j} + γ \left(\frac{\partial {f}_{i}}{\partial {s}_{k , i}^{j}}\right) , k = 1 , 2 , 3 , … , N$$

In the process, a length of the change 213 can be scaled using a scaling factor γ. Using the formulas:

$${γ}_{s} = {\left(\frac{{\partial }^{2} {f}_{i}}{\partial {s}_{k , i}^{j} {}^{2}}\right)}^{- 1}$$

$$\text{and} {γ}_{c} = {\left(\frac{{\partial }^{2} {f}_{i}}{\partial {c}_{k , i}^{j} {}^{2}}\right)}^{- 1}$$

the scaling factor can be calculated for both Fourier coefficients. As a result, a similar or identical convergence rate can be obtained for the parameters.

In the event that the change 213 is such that the predetermined range 225 would be departed from, a further adjustment can then be carried out. In this case, the change 213 can be adjusted such that the second measurement signal 212 no longer departs from the predetermined range.

FIG. 5 is a diagram 200 that corresponds to the diagram in FIG. 4 unless any differences are described below. This example shows the case where the excursion is greater than intended by the predetermined range 225, meaning that a corresponding adjustment can be carried out. The second measurement signal 212 is reduced such that the second measurement signal 212 has an excursion that corresponds to the maximum excursion 222. This can be described, for example, using the formulas:

$${{′}^{}}_{k , i} = \left\{\begin{matrix}{k , i}_{} , \text{for} {P}_{k , i}^{m i n} \leq β \leq {P}_{k , i}^{m a x} \\ \left(\frac{{P}_{k , i}^{m i n}}{β}\right) {k , i}_{} , \text{for} β < {P}_{k , i}^{m i n} \\ \left(\frac{{P}_{k , i}^{m a x}}{β}\right) {k , i}_{} , \text{for} β > {P}_{k , i}^{m a x}\end{matrix}\right) ,$$

$$k = 0 , 1 , … , N$$

$${{′}^{}}_{k , i} = \left\{\begin{matrix}{k , i}_{} , \text{for} {P}_{k , i}^{m i n} \leq β \leq {P}_{k , i}^{m a x} \\ \left(\frac{{P}_{k , i}^{m i n}}{β}\right) {k , i}_{} , \text{for} β < {P}_{k , i}^{m i n} \\ \left(\frac{{P}_{k , i}^{m a x}}{β}\right) {k , i}_{} , \text{for} β > {P}_{k , i}^{m a x}\end{matrix}\right) ,$$

$$k = 1 , 2 , … , N$$

where

$$β = p \left({k , i}_{} , {k , i}_{}\right)$$

Where an adjustment is carried out in relation to the excursion, this may already change the direction such that the direction is between the minimum angle 223 and the maximum angle 224.

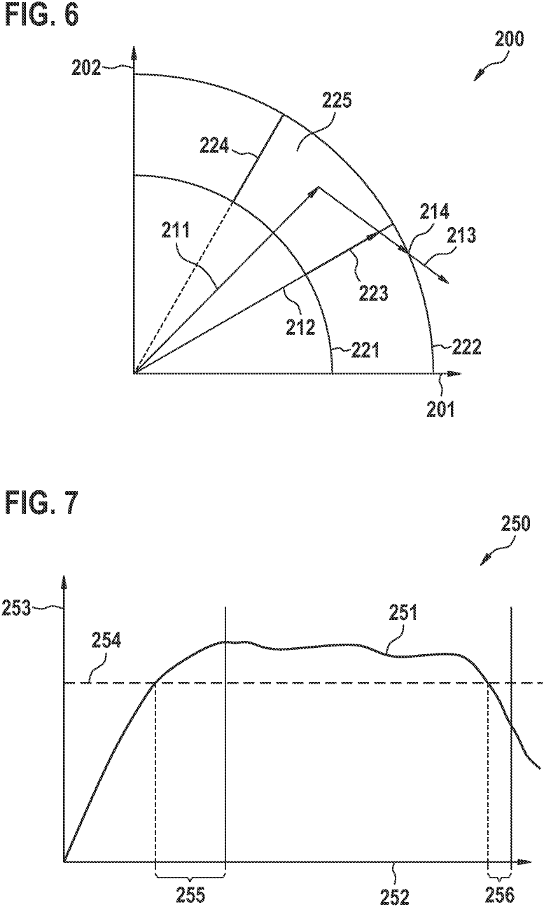

FIG. 6 is a diagram 200 that corresponds to the diagram in FIGS. 4 or 5 unless any differences are described below. This example also shows the case where the excursion is greater than intended by the predetermined range 225, meaning that a corresponding adjustment can be carried out. First, the second measurement signal 212 is reduced in a similar way to the method explained in relation to FIG. 5. This is shown by way of the interim change 214. The boundary conditions for the excursion are now satisfied, but the boundary conditions for the direction are not adhered to. Therefore, the direction is now additionally adjusted. This can be done by first calculating the phase using the formula:

$$\text{Δ} {θ}_{k , i}^{j} = {tan}^{- 1} \left(\frac{\partial {f}_{i}}{\partial {c}_{k , i}^{j}} / \frac{\partial {f}_{i}}{\partial {s}_{k , i}^{j}}\right) ,$$

$$k = 1 , 2 , … , N$$

and then a summated phase change can be carried out using the formula:

$$a \left({k , i}_{} , {k , i}_{}\right) = {\sum }_{j = 1}^{K} \text{Δ} {θ}_{k , i}^{j} , k = 1 , 2 , … , N$$

It can then be checked whether the direction is within the predetermined boundary conditions, it being possible to use the following formulas:

$$g \left(α\right) = \left\{\begin{matrix}α - {\text{Θ}}_{k , i}^{m a x} , \text{if} α > {\text{Θ}}_{k , i}^{m a x} \\ α - {\text{Θ}}_{k , i}^{m i n} , \text{if} α < {\text{Θ}}_{k , i}^{m i n} \\ α , \text{if} {\text{Θ}}_{k , i}^{m i n} \leq α \leq {\text{Θ}}_{k , i}^{m a x}\end{matrix}\right)$$

In the process,

$$α = a \left({k , i}_{} , {k , i}_{}\right)$$

can be used.

The Fourier coefficients can be adjusted when

$$α > {\text{Θ}}_{k , i}^{m a x} \text{or} α < - {\text{Θ}}_{k , i}^{m a x}$$

This can be done using the equations:

$${{″}^{}}_{k , i} = {{′}^{}}_{k , i} cos \left(g \left(α\right)\right) - {{′}^{}}_{k , i} sin \left(g \left(α\right)\right)$$

$${{″}^{}}_{k , i} = {{′}^{}}_{k , i} sin \left(g \left(α\right)\right) + {{′}^{}}_{k , i} cos \left(g \left(α\right)\right)$$

It may be provided that the boundary conditions, i.e., the minimum excursion 221, the maximum excursion 222, the minimum angle 223, and the maximum angle 224, are not implemented for each pass of the method but only during each second, third, etc., pass.

Lastly, a smoothing filter may also be used, which can be described using the formulas:

$${c}_{k , i}^{j + 1} = \left(1 - {ε}_{1}\right) {{″}^{}}_{k , i} + {ε}_{1} {c}_{k , i}^{j} , k = 0 , 1 , 2 , … N$$

$${s}_{k , i}^{j + 1} = \left(1 - {ε}_{1}\right) {{″}^{}}_{k , i} + {ε}_{1} {s}_{k , i}^{j} , k = 1 , 2 , 3 , … N$$

The smoothing filter can be initialized using predetermined coefficients, for example:

$${c}_{k , i}^{0} = {c}_{k , i}$$

it being possible to configure a filter parameter ∈₁ for each fitness or sports exercise.

In one exemplary embodiment, the predetermined range 225 is selected on the basis of the classified movement sequence. Therefore, classification errors in particular can be reduced further.

In one exemplary embodiment, the information ascertained from the sensor data on the basis of the mathematical model is also used for classifying the movement. This can further improve the classification.

Using the predetermined ranges 225 shown in FIGS. 4 to 6, measurement data that point to a different fitness or sports exercise can be disregarded. Additionally, using the coefficients, in particular Fourier coefficients, that can be adjusted in the predetermined ranges 225, user-specific different executions of the fitness or sports exercises, or an altered execution of the fitness or sports exercises owing to fatigue, can be taken into account in the classification and in the determination of the measured variable that is characteristic of the movement sequence. This allows for an improved classification method, an improved arithmetic logic unit 130, and an improved sensor system 120.

FIG. 7 shows a curve 250 of an activity rate 251 for activating and deactivating an adjustment. In this case, an excursion 253 is plotted as a function of a time axis 252. If the activity rate 251 exceeds a threshold value 254 for a first time period 255, the coefficient, for example the above-described Fourier coefficient, can be adjusted. Consequently, the at least one coefficient can be adjusted on the basis of the sensor data only when the classified movement is executed for a predetermined first time period 255.

This can be used in particular when a technique of a user, for example the person 150 in FIG. 3, for executing the fitness or sports exercise diverges from an ideal technique. For the Fourier coefficients, a standard value can then be calculated for each dimension using the formula:

$${e}_{i} = 0.5 {\left({c}_{0 , i}\right)}^{2} + 0.5 {\sum }_{k = 1}^{N} {\left({c}_{k , i}\right)}^{2} + {\left({s}_{k , i}\right)}^{2}$$

Using the formula:

$$E = \frac{1}{ω} {\sum }_{i = 1}^{M} {e}_{i} / {σ}_{i}$$

a summation can then be carried out by way of the sensor dimensions, and standardization can be carried out using the sensor noise σᵢ; the accepted frequency ω of the corresponding exercise is also used for the standardization.

An activity rate can then be calculated and filtered using the formulas:

$${p}_{j} = {ε}_{2} {σ}_{i}^{- 1} d {t}^{- 1} {\sum }_{i = 1}^{M} {h}_{i} \left({θ}_{j} , {r}_{i}\right) \left({y}_{j} - \frac{1}{2} {h}_{i} \left({θ}_{j} , {r}_{i}\right)\right) + \left(1 - {ε}_{2}\right) {p}_{j - 1}$$

$${r}_{j} = \left\{\begin{matrix}1 , \text{for} {p}_{j} \geq E \\ 0 , {\text{for p}}_{j} < 0 \\ \frac{{p}_{j}}{E} , \text{else}\end{matrix}\right)$$

The activity rate describes how close the execution of the fitness or sports exercise is to a predetermined pattern. If the activity rate 251 exceeds the threshold value 254 for the first predetermined time period 255, the Fourier coefficients can be adjusted. If the activity rate 251 is below the threshold value 254 for the second predetermined time period 256, the adjustment of the Fourier coefficients can be terminated. The first time period 255 and the second time period 256 may be identical, but may also be different.

Although the present invention has been described in detail using the preferred exemplary embodiments, the present invention is not limited to the disclosed examples and a person skilled in the art may derive other variations therefrom without departing from the scope of the present invention.

What is claimed is:

1. A method for classifying movements, comprising the following steps:
receiving sensor data;
classifying a movement sequence, wherein a characteristic measured variable ascertained from the sensor data is used for the classifying;
reading in the sensor data into a mathematical model, wherein the mathematical model includes at least one coefficient and is dependent on the characteristic measured variable, and wherein the mathematical model is selected on based on the movement sequence;
determining an equation of state of a sensor data value, wherein the equation of state includes the at least one coefficient and wherein the sensor data value maps a curve of the characteristic measured variable;
adjusting the at least one coefficient based on the sensor data, wherein the coefficient is additionally kept within a predetermined range during the adjustment;
adjusting the mathematical model based on the adjusted coefficient; and
outputting an item of information, wherein a type of the classified movement sequence is part of the information.

2. The method as recited in claim 1, wherein the predetermined range is selected based on the classified movement sequence.

3. The method as recited in claim 1, wherein the sensor data are predicted based on the adjusted mathematical model.

4. The method as recited in claim 1, wherein the reading in of the sensor data into the mathematical model, the determining of the equation of state of the sensor data value, the adjusting of the at least one coefficient, and the adjusting of the mathematical model are each carried out multiple times.

5. The method as recited in claim 1, wherein the information additionally includes a measured variable that is characteristic of the movement sequence.

6. The method as recited in claim 1, wherein the mathematical model includes a Kalman filter, or an expanded Kalman filter, or an unscented Kalman filter.

7. The method as recited in claim 1, wherein the equation of state of the sensor data value includes a Fourier series, wherein the characteristic measured variable includes a frequency of a movement, wherein the at least one coefficient is a Fourier coefficient of the Fourier series, and wherein the predetermined range is determined based on Fourier coefficients of the Fourier series.

8. The method as recited in claim 7, wherein an excursion and a phase are determined using the Fourier coefficients, wherein a maximum adjustment amount is used when adjusting the Fourier coefficients, wherein the maximum adjustment amount is selected such that, in the event that the predetermined range is departed from, the excursion is scaled such that the excursion is within the predetermined range, and, in the event that the predetermined range is departed from due to the phase once the excursion has been scaled, the phase is changed such that the predetermined range is adhered to.

9. The method as recited in claim 1, wherein information ascertained based on the mathematical model and the sensor data is also used to classify the movement sequence.

10. The method as recited in claim 1, wherein the adjusted coefficient and the adjusted model are stored in a memory.

11. The method as recited in claim 1, wherein the at least one coefficient is adjusted based on the sensor data only when the classified movement sequence is executed for a predetermined time period.

12. The method as recited in claim 1, wherein at least one further coefficient is added to the mathematical model when it is established that the sensor data are then a better fit for the mathematical model.

13. An arithmetic logic unit, comprising:
a signal input;
a processor; and
a signal output;
wherein the processor includes a program that causes the arithmetic logic unit to receive sensor data via the signal input, and then to:
classify a movement sequence, wherein a characteristic measured variable ascertained from the sensor data is used for the classifying,
read in the sensor data into a mathematical model, wherein the mathematical model includes at least one coefficient and is dependent on the characteristic measured variable, and wherein the mathematical model is selected on based on the movement sequence,
determine an equation of state of a sensor data value, wherein the equation of state includes the at least one coefficient and wherein the sensor data value maps a curve of the characteristic measured variable,
adjust the at least one coefficient based on the sensor data, wherein the coefficient is additionally kept within a predetermined range during the adjustment,
adjust the mathematical model based on the adjusted coefficient, and
output, via the signal output, an item of information, wherein a type of the classified movement sequence is part of the information.

14. The arithmetic logic unit as recited in claim 13, further comprising:
a memory, wherein the processor includes a program that causes the arithmetic logic unit to store the adjusted coefficient and the adjusted model in the memory.

15. A sensor system, comprising:
a sensor configured to determine sensor data; and
an arithmetic logic unit, including:
a signal input,
a processor, and
a signal output,
wherein the processor includes a program that causes the arithmetic logic unit to receive the sensor data via the signal input, and then to:
classify a movement sequence, wherein a characteristic measured variable ascertained from the sensor data is used for the classifying,
read in the sensor data into a mathematical model, wherein the mathematical model includes at least one coefficient and is dependent on the characteristic measured variable, and wherein the mathematical model is selected on based on the movement sequence,
determine an equation of state of a sensor data value, wherein the equation of state includes the at least one coefficient and wherein the sensor data value maps a curve of the characteristic measured variable,
adjust the at least one coefficient based on the sensor data, wherein the coefficient is additionally kept within a predetermined range during the adjustment,
adjust the mathematical model based on the adjusted coefficient, and
output, via the signal output, an item of information, wherein a type of the classified movement sequence is part of the information,
wherein the sensor is connected to the signal input and the sensor data ascertained using the sensor is communicated to the signal input.
